(19) United States
(12) Patent Application Publication
(10) Pub. No.: US 2021/0400604 A1
(43) Pub. Date: Dec. 23, 2021

(54) METHODS AND DEVICES FOR SIDELINK COMMUNICATION

(71) Applicant: NEC CORPORATION, Tokyo (JP)

(72) Inventor: Gang WANG, Beijing (CN)

(73) Assignee: NEC CORPORATION, Tokyo (JP)

(21) Appl. No.: 17/284,290

(22) PCT Filed: Oct. 11, 2018
(86) PCT No.: PCT/CN2018/109900

§ 371 Date: Apr. 9, 2021

(51) Int. Cl. H04W 52/52; H04W 52/36; H04W 4/40

(52) U.S. Cl. CPC H04W 52/52; H04W 4/40; H04W 52/367

(57) ABSTRACT

Embodiments of the present disclosure relate to a method, a device and a computer readable medium for sidelink communication. In an embodiment, a configuration of a resource set for Time Division Multiplexing (TDM) in vehicle-to-everything (V2X) communication between the first terminal device and a second terminal device is determined. The resource set corresponds to a plurality of symbols in the time domain. The configuration specifies an Automatic Gain Control (AGC) signal is to be transmitted in an initial symbol of the plurality of symbols, the AGC signal being determined based on control information for the V2X communication. The V2X communication based on the configuration is performed. As a result, when a PSCCH and PSSCH are TDMed, the AGC can be accurately implemented.

### TECHNICAL FIELD

Embodiments of the present disclosure generally relate to the field of telecommunication, and in particular, to methods, devices and computer readable mediums for sidelink communication.

### BACKGROUND

Device to device (D2D) communication has been developed for years and have been extended to include vehicle-to-everything (V2X) communication. For example, in current telecommunication specifications such as the 3rd generation partnership project (3GPP) specification Release 14, the extensions for the D2D work consist of support of V2X communication. V2X communication includes any combination of direct communication between vehicles, pedestrians, infrastructures, and networks, and thus can be divided into the following four different types: Vehicle-to-Vehicle (V2V), Vehicle-to-Pedestrian (V2P), Vehicle-to-Infrastructure (V2I), Vehicle-to-Network (V2N). V2V communication includes communication between vehicles; V2P communication includes communication between a vehicle and a device carried by an individual (for example, a handheld user terminal carried by a pedestrian, cyclist, driver, or passenger); V2I communication includes communication between a vehicle and infrastructures supporting V2X applications, such as roadside units (RSUs) which are transportation infrastructure entities; and V2N communication includes communication between a vehicle and network infrastructures such as a network terminal.

In addition, the New Radio (NR) V2X technology supports advanced V2X services which may be categorized into four use case groups: vehicles platooning, extended sensors, advanced driving and remote driving.

### SUMMARY

In general, example embodiments of the present disclosure provide methods, devices and computer readable mediums for side link communication.

In a first aspect, embodiments of the present disclosure provide a method implemented at a first terminal device. In this method, a configuration of a resource set for Time Division Multiplexing (TDM) in V2X communication between a control channel and a data channel is determined. The resource set corresponds to a plurality of symbols in the time domain. The configuration specifies an Automatic Gain Control (AGC) signal is to be transmitted in an initial symbol of the plurality of symbols. The AGC signal is determined based on control information for the V2X communication. In the method, the V2X communication based on the configuration is performed with a second terminal device.

In a second aspect, embodiments of the present disclosure provide a terminal device. The terminal device comprises a processor and a memory coupled to the processing unit and storing instructions thereon. The instructions, when executed by the processing unit, causing the device to perform the method according to the first aspect.

In a third aspect, embodiments of the present disclosure provide a computer readable medium having instructions stored thereon. The instructions, when executed on at least one processor, causing the at least one processor to carry out the method according to the first aspect.

Other features of the present disclosure will become easily comprehensible through the following description.

### BRIEF DESCRIPTION OF THE DRAWINGS

Through the more detailed description of some embodiments of the present disclosure in the accompanying drawings, the above and other objects, features and advantages of the present disclosure will become more apparent, wherein:

FIG. 1 is a schematic diagram of a communication network in which embodiments of the present disclosure can be implemented;

FIG. 2 illustrates an schematic configuration of a sub-channel with TDM of physical sidelink control channel (PSSCH) and physical sidelink shared channel (PSCCH) according to some embodiments of the present disclosure;

FIGS. 3A and 3B illustrate configurations of a SCORESET according to some embodiments of the present disclosure, respectively;

FIG. 4 shows a configuration of a SCORESET according to some embodiments of the present disclosure;

FIG. 5 shows a configuration of a SCORESET according to some embodiments of the present disclosure;

FIG. 6 is a schematic diagram shows frequency division multiplexing of PSSCH and PSCCH according to some embodiments of the present disclosure;

FIG.7 shows a flowchart of an method for sidelink communication according to some embodiments of the present disclosure; and

FIG. 8 is a simplified block diagram of a device that is suitable for implementing embodiments of the present disclosure.

Throughout the drawings, the same or similar reference numerals represent the same or similar element.

### DETAILED DESCRIPTION

Principle of the present disclosure will now be described with reference to some example embodiments. It is to be understood that these embodiments are described only for the purpose of illustration and help those skilled in the art to understand and implement the present disclosure, without suggesting any limitations as to the scope of the disclosure. The disclosure described herein can be implemented in various manners other than the ones described below.

In the following description and claims, unless defined otherwise, all technical and scientific terms used herein have the same meaning as commonly understood by one of ordinary skills in the art to which this disclosure belongs.

As used herein, the term “network device” or “base station” (BS) refers to a device which is capable of providing or hosting a cell or coverage where terminal devices can communicate. Examples of a network device include, but not limited to, a Node B (NodeB or NB), an Evolved NodeB (eNodeB or eNB), a NodeB in new radio access (gNB), a next generation NodeB (gNB), a Remote Radio Unit (RRU), a radio head (RH), a remote radio head (RRH), a low power node such as a femto node, a pico node, and the like. For the purpose of discussion, in the following, some embodiments will be described with reference to eNB as examples of the network device.

As used herein, the term “terminal device” refers to any device having wireless or wired communication capabilities. Examples of the terminal device include, but not limited to, user equipment (UE), personal computers, desktops, mobile phones, cellular phones, smart phones, personal digital assistants (PDAs), portable computers, image capture devices such as digital cameras, gaming devices, music storage and playback appliances, or Internet appliances enabling wireless or wired Internet access and browsing and the like.

As used herein, the singular forms “a”, “an” and “the” are intended to include the plural forms as well, unless the context clearly indicates otherwise. The term “includes” and its variants are to be read as open terms that mean “includes, but is not limited to.” The term “based on” is to be read as “based at least in part on.” The term “one embodiment” and “an embodiment” are to be read as “at least one embodiment.” The term “another embodiment” is to be read as “at least one other embodiment.” The terms “first,” “second,” and the like may refer to different or same objects. Other definitions, explicit and implicit, may be included below.

In some examples, values, procedures, or apparatus are referred to as “best,” “lowest,” “highest,” “minimum,” “maximum,” or the like. It will be appreciated that such descriptions are intended to indicate that a selection among many used functional alternatives can be made, and such selections need not be better, smaller, higher, or otherwise preferable to other selections.

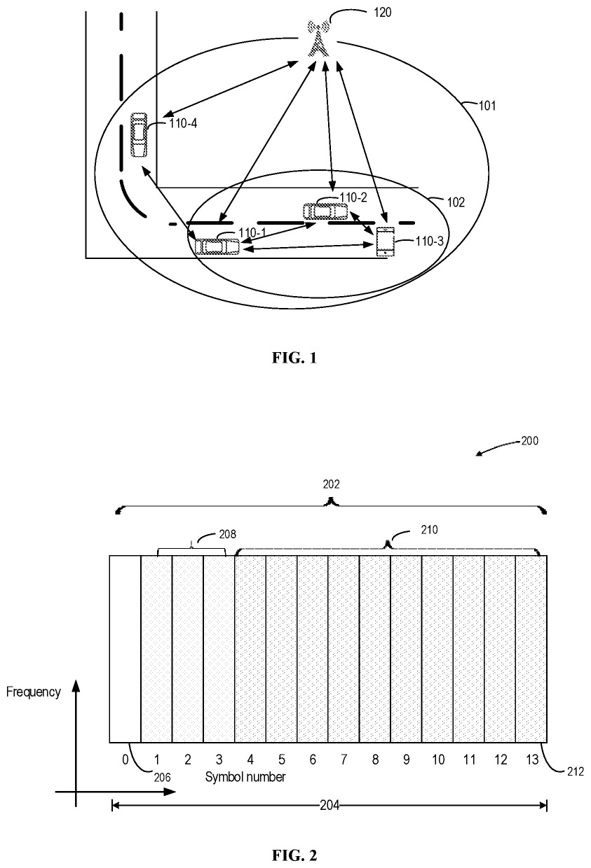

FIG. 1 shows an example communication environment 100 in which embodiments of the present disclosure can be implemented. In the environment 100, vehicles 110-1-110-3 and a personal mobile device 110-4 are terminal devices (collectively or individually referred to as terminal device 110) and can communicate with each other. A cellular network device 120 is also deployed in the environment and provides services to those terminal devices that are in their coverage 101 and access to the cellular network. It would be appreciated that the terminal devices and the links there between are shown merely for illustration. There may be various other terminal devices and network devices in V2X communication in many other ways.

The network device 120 may divide different zones according to the relative location with the terminal device 110 (or according to the absolute location of the terminal device 110), such as the coverage 102 (also referred to as zone 102) shown in FIG. 1. Some terminal devices may locate in zone 102 (for example, terminal device 110-1, 1110-2 and 110-4) and some terminal device may locate outside of zone 102 (for example, terminal device 110-3). The terminal devices located in different zones may also communicate with each other.

The environment 100 illustrates a scenario of V2X communication where vehicles and any other devices (a network device 120) can communicate with each other. As mentioned above, V2X communication can be divided into four types, including Vehicle-to-Vehicle (V2V), Vehicle-to-Pedestrian (V2P), Vehicle-to-Infrastructure (V2I), Vehicle-to-Network (V2N). Communication between terminal devices 110 (that is, V2V, V2P, V2I communications) can be performed via both Uu interface and direct links (or sidelinks), while communication involving the network device 120 (that is, V2N communication) can be performed only via the Uu interfaces. For sidelink-based V2X communication, information is transmitted from a TX terminal device to one or more RX terminal devices in a broadcast manner.

Depending on the communication technologies, the network 100 may be a Code Division Multiple Access (CDMA) network, a Time Division Multiple Address (TDMA) network, a Frequency Division Multiple Access (FDMA) network, an Orthogonal Frequency-Division Multiple Access (OFDMA) network, a Single Carrier-Frequency Division Multiple Access (SC-FDMA) network or any others. Communications discussed in the network 100 may use conform to any suitable standards including, but not limited to, New Radio Access (NR), Long Term Evolution (LTE), LTE-Evolution, LTE-Advanced (LTE-A), Wideband Code Division Multiple Access (WCDMA), Code Division Multiple Access (CDMA), cdma2000, and Global System for Mobile Communications (GSM) and the like. Furthermore, the communications may be performed according to any generation communication protocols either currently known or to be developed in the future. Examples of the communication protocols include, but not limited to, the first generation (1G), the second generation (2G), 2.5G, 2.75G, the third generation (3G), the fourth generation (4G), 4.5G, the fifth generation (5G) communication protocols. The techniques described herein may be used for the wireless networks and radio technologies mentioned above as well as other wireless networks and radio technologies. For clarity, certain aspects of the techniques are described below for LTE, and LTE terminology is used in much of the description below.

In V2X communication, a sidelink is used for ProSe direct communication between e.g., UEs. A PSSCH and a PSCCH are defined in 3GPP as two of the physical channels of the sidelink. A basic (minimum) resource unit in time domain is a slot (or sub-frame). Meanwhile, there may be a plurality of symbols in the slot in the time domain. The sub-frame may be flexibly multiplexed in frequency domain (or FDMed) with the PSSCH and PSCCH.

Currently, in LTE-V2X, the PSCCH and PSSCH are FDMed, and are mapped from the first symbol (that is, an initial symbol) in a subframe. When the subframe as such is received by a receiving UE, it can use the first symbol for AGC settling. Another possible solution is that the PSCCH and PSSCH are TDMed in NR-V2X; however, since reception power on different symbols of a slot may be different, AGC on the first symbol as LTE sidelink may be not accurate. However, without an accurate AGC, signals received at the receiver would vary which will impact the performance at the receiver. As a result, it is needed to find a solution which provides a configuration of a resource set so that when the PSCCH and PSSCH are TDMed, the AGC can be accurately implemented.

FIG. 2 illustrate a schematic configuration of a sub-channel 200 with TDM of PSSCH and PSCCH according to some embodiments of the present disclosure. As shown in FIG. 2, the sub-channel 200 occupies a slot 204 in the time domain. The sub-channel 200 comprises a plurality of contiguous resource blocks 202 (RBs) in a same slot 204. In this example, the time slot 204 may include a plurality of symbols. In some embodiments, the symbols may be OFDM or SC-FDMA symbols. Among the 14 symbols, an initial symbol 206, the Symbol 0 shown in FIG2, may be used for AGC. That is, an AGC signal is carried in the initial symbol 206 for AGC settling.

According to embodiments of the present disclosure, the terminal device 110 may determine a configuration of a resource set as mentioned above in V2X communication between a control channel and a data channel, for example, the PSCCH and the PSSCH. The AGC signal is determined based on control information for the V2X communication. The V2X communication can be performed based on a configuration as such.

The sub-channel may be configured with one or a plurality of sidelink control time-frequency resource set 208 (SCORESET) for the PSCCH per e.g. sub-channel. In some other embodiments, the one or a plurality of SCORESET for the PSCCH may also be configured per resource pool, per bandwidth, per bandwidth part etc. which is not limited herein. Since the principle thereof is the same, the structure will not be repeated herein.

In some embodiments, when one SCORESET 208 is configured or preconfigured, the bandwidth of the SCORESET 208 may be always equal to the resource pool, bandwidth, bandwidth part, or sub-channel. In some further embodiments, when a plurality of SCORESETs are configured (not shown), the initial symbol 206 and the duration of each SCORESET 208 are the same, bandwidth of different SCORESET 208 do not overlap with each other.

One SCORESET 208 is always associated with one PSSCH time-frequency resource set in a slot, and a plurality of SCORESETs may be associated with a single PSSCH time-frequency resource set.

In the embodiments, as shown in FIG. 2, the sub-channel 200 is configured with a PSSCH resource set 210 which the above mentioned SCORESET 208 is associated with. An ending symbol 212, that is the last symbol in the sub-channel 200, is configured to be a part of the PSSCH resource set 210. In some embodiments, the ending symbol 212 is not limited to be part of the PSSCH resource set 210 as shown in FIG. 2 and may carry other kind of information or is void.

In some other embodiments, one symbol of the SCORESET may carry both the control information to be transmitted on the PSSCH and other data to be transmitted on the PSCCH (not shown).

Additionally, in some embodiments, when only one supportable aggregation level is (pre-)configured in each SCOREST, supportable aggregation level for different SCORESET may be different; in case of multiple aggregation levels are supported in each SCORSET, the UE may select an aggregation level according to a base station instruction or sidelink channel status.

In some embodiments, the transmission power on PSSCH and that of PSCCH may be configured in a variety of ways.

In some embodiments, when a terminal device transmits data with the PSCCH and PSSCH that are not on the same symbol, the terminal device may configure that the transmission power of the PSCCH on some symbol is proportional to the associated PSSCH transmission power on another symbol. As such, the transmission power to be transmitted by the terminal device across the slot 204 does not vary beyond an AGC range, thereby obtaining an accurate AGC. In one example, transmission power of PSCCH may be always the same as the associated PSSCH power.

In some other embodiments, when a terminal device transmits data with the PSCCH and PSSCH on a same symbol, the terminal device may configure to ensure that a difference between a max transmission power and a min transmission power across all symbols in the time slot 204 is smaller than X dBm. As a result, a configuration as such may be transmitted by the terminal device. In one example, X may be 0.01 dBm but is not limited to it. X may be any value which depends on requirements and actual needs. The value of X may be preconfigured or specified.

Alternatively, when a terminal device performs transmission on both the PSCCH and PSSCH in a single symbol, the terminal device may configure to ensure that the transmission power on the symbols where the PSCCH is used for transmission is the same as the transmission power on the symbols where PSSCH is used for transmission. That is, a total transmission power on the symbol on which both the PSCCH and PSSCH are used is the same as that of the symbols on which e.g. only PSSCH is used. As a result, a configuration as such may be transmitted by the terminal device.

In one embodiment, the transmission power on PSCCH may be higher than PSSCH transmission power on the same symbol if there is.

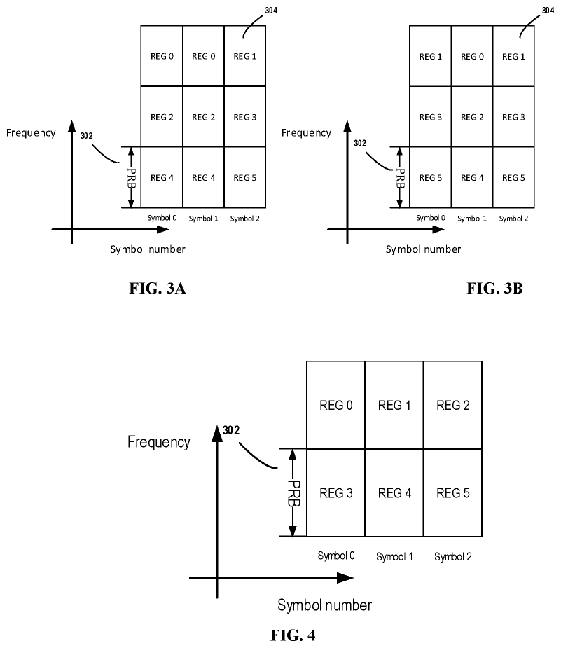

According to the embodiments of the present disclosure, when the TDM of PSSCH and PSCCH is used, there may be a variety of ways for configuring the AGC settings. FIGS. 3-5 illustrate three different schemes regarding the configurations, respectively. It is to be understood that these schemes are discussed for examples, rather than suggesting any limitation. There may be other suitable ways to determine the configuration.

As a first scheme, FIGS. 3A and 3B separately illustrate a configuration of a SCORESET according to some embodiments of the present disclosure. The configuration may be determined by a terminal device, for example, the terminal device 110 shown in FIG. 1. It is to be understood this is discussed for illustration rather than limitation. In some alternative embodiments, the configuration may be determined by a network device for example, the network device 120 as shown in FIG. 1, or other suitable device or controller.

As shown in FIGS. 3A and 3B in a frequency domain, one physical resource block (PRB) 302 may comprise a plurality of subcarriers. The PRB 302 is the minimum resource unit in the frequency domain.

In some embodiments, as shown in FIG. 3A, there are three PRBs 302 in a SCORESET 208. In some embodiments, a PDCCH-like physical layer structure is used for the PSCCH, and the SCORESET 208 comprises a plurality of resource element groups 304 (REGs). In one example, the REG may equal one resource block during one OFDM symbol. In some other embodiments, a PUSCH-like physical layer structure is used for PSCCH. The physical layer structure used for PSCCH may also be others based on requirements and applied scenarios but is not limited here.

In the current embodiments, there are three resource element groups 304 in one PRB 302 and 12 resource elements groups 304. The example used here is only for illustration purpose. In real implementations, the number of PRB and the REGs may vary according to specific requirements and needs.

The FIG. 3A also illustrates a way of mapping the PSCCH to the SCORESET 208. As shown in FIG. 3A, the SCORESET 208 starts from the second symbol, that is Symbol 1, in a slot, and the PSCCH is mapped within SCORESET. In addition, an AGC signal to be transmitted on the first symbol is a replication of one of the SCORESET symbol. That is, the AGC signal is a part of the control information to be transmitted in a symbol in the SCORESET after an initial symbol. In this specific example shown in FIG. 3A, the AGC signal value in symbol 0 is equal to the value of the control information to be transmitted in symbol 1. In this specific example shown in FIG. 3B, the AGC signal value in symbol 0 is equal to the value of the control information to be transmitted in symbol 2.

In some embodiments, the replication of the part of the control information to be transmitted in a symbol after the initial symbol is configured by the UE, and configured as the AGC signal. Additionally, based on the configuration, the part of the control information, that is, the AGC signal is transmitted in the initial symbol from the first terminal device to the second terminal device. As a result, the second terminal received the configuration as shown in FIG. 3A.

Alternatively, as shown in FIG. 4, the AGC signal value to be transmitted is a part of the control information. The part is different from the remaining part of the control information to be transmitted in one or more symbols, e.g., Symbol 1 and Symbol 2, after the initial symbol. Additionally, based on the configuration, the part of the control information is transmitted in the initial symbol between the terminal devices, e.g., terminal devices 110-1, 110-2, 110-3 . . . .

In some embodiments, the part as mentioned above is determined by the terminal device, and is configured as the AGC signal.

In some embodiments, the configuration may be configured locally as mentioned above. Alternatively, the configuration may also be received from another terminal device or a network device managing the first and second terminal devices.

In some embodiments, the transmission power on the initial symbol 206 is the same as the transmission power on the symbols of the SCORESET 208.

As a second scheme, FIG. 4 shows configuration of a SCORESET according to some embodiments of the present disclosure.

In some embodiments as shown in FIG. 4, a PDCCH-like physical layer structure is used for the PSCCH, and the SCORESET 208 comprises a plurality of REGs 304. In some other embodiments, a PUSCH-like physical layer structure is used for PSCCH. Alternatively, the physical layer structure used for PSCCH may also be others based on requirements and scenarios thus, is not limited here.

The FIG. 4 also illustrates a way of mapping the PSCCH to the SCORESET 208. As shown in FIG. 4, the SCORESET 208 starts from the first symbol, that is Symbol 0, in a slot, and the PSCCH is mapped within SCORESET.

In some embodiments, transmission power of the PSCCH is the same as transmission power of associated PSSCH.

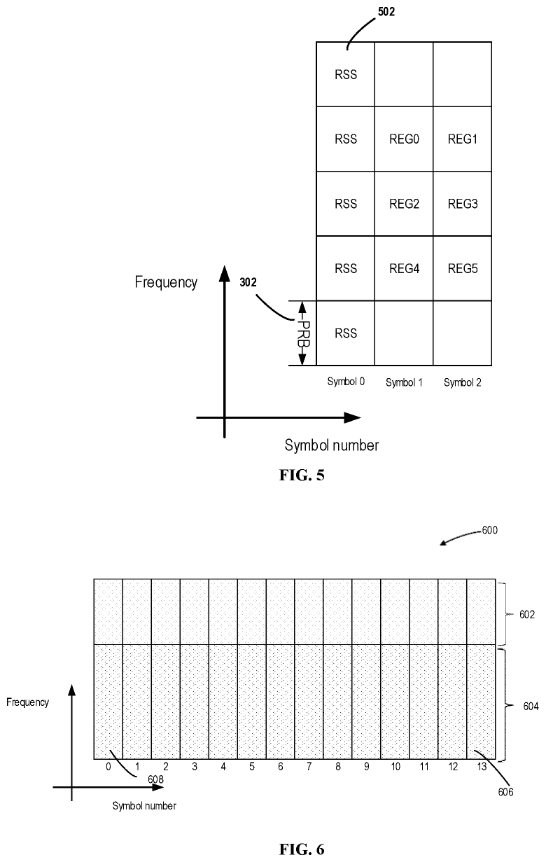

As a third scheme, FIG. 5 shows configuration of a SCORESET according to some embodiments of the present disclosure.

In the embodiments as shown in FIG. 5, a PDCCH-like physical layer structure is used for the PSCCH, and the SCORESET 208 comprises a plurality of REGs 304. In some other embodiments, a PUSCH-like physical layer structure is used for PSCCH. Alternatively, the physical layer structure used for PSCCH may also be others based on requirements and scenarios thus, is not limited here.

FIG. 5 also illustrates a way of mapping the PSCCH to the SCORESET 208. As shown in FIG. 5, the SCORESET 208 starts from the second symbol, that is Symbol 1, in a slot, and the PSCCH is mapped within SCORESET. In addition, a reference signal sequence 502 (RSS) is transmitted on the first symbol, namely, Symbol 0 as shown in FIG. 5. In the embodiments, the RSS 502 may be used for channel estimation including CSI measurement and pathloss measurement in unicast/groupcast of NR-V2X. The RSS 502 may be implemented with wideband reference signals.

First, the sequence of the RSS 502 may be a pseudo noise (PN) sequence, a Zadoff-Chu (ZC) sequence, or a computer generated sequence (CGS). How

Second, the RSS 502 may be transmitted with a comb manner. The number of combs may be configured or pre-configured per resource pool, per bandwidth, per bandwidth part, or per sub-channel.

In some embodiments, the RSS 502 may be transmitted with different cyclic shift values. The allowed cyclic shift values may be configured or preconfigured per resource pool, per bandwidth, per bandwidth part, or per sub-channel. In some embodiments, one RSS 502 may be identified by a pair of {comb offset, cyclic shift value} used by the RSS 502.

In some embodiments, the comb offset and cyclic shift for the RSS 502 used by a UE may be designated by a base station, or one-to-one associated with a PSCCH resource, or one-to-one associated with a PSSCH resource. The comb offset and cyclic shift for the RSS 502 may be also related to a transmitting mode. The transmission mode may be broadcast, groupcast or unicast of the UE, but is not limited herein.

In one example, only one pair of allowed {comb offset, cyclic shift value} pair is configured or pre-configured for broadcast per resource pool, per bandwidth, per bandwidth part, or per sub-channel.

In another example, allowed {comb offset, cyclic shift value} pairs for unicast and/or groupcast are different from that for broadcast. When the transmission mode is unicast or groupcast, at least one of the comb offset, cyclic shift, or a scrambling ID for initialization of the RSS 502 is derived from a destination ID and/or source ID of the unicast or groupcast. As such, a receiver can differentiate the signal received is from which terminal device.

In some embodiments, the transmission mode may be indicated by a higher layer (e.g., a media access control (MAC) layer or an application layer) to the physical layer of a UE.

In some embodiments, the transmission power of the RSS 502 may be proportional to the transmission power of the associated PSCCH or PSSCH. For example, the transmission power of the RSS 502 is the same as associated PSCCH, or associated PSSCH.

In one embodiment, the above three schemes as shown in FIGS. 3-5 respectively may be configured for different resource pools, different bandwidths, different bandwidth parts, or different sub-channels. When the second scheme as shown in FIG. 4, is configured for a resource pool, a bandwidth, a bandwidth part, or a sub-channel, from a receiving UE point of view, the receiving UE is expected to decode the first symbol. Alternatively, the receiving UE is expected to decode the first symbol if it is configured or preconfigured to do so in the resource pool, bandwidth, bandwidth part, or sub-channel; the UE is not expected to decode the first symbol otherwise.

In all the schemes above, the UE transmits the PSCCH or the RSS 502 from the beginning of the first symbol of the slot.

In some embodiments, for a PSSCH, a rate matching is applied only over resources used for transmission with the PSCCH, and resources used for reference signal transmission; UE should transmit PSSCH on the last symbol of the slot.

In a Tx/Rx switching scenario, there is a switching between actions of transmitting and receiving in a terminal device. From a receiving terminal device perspective, before its receiving, the terminal device performs a transmission and there is data in an ending symbol of the plurality of symbols for the V2X communication in the transmission. For such kind of scenario, a stopping position in the ending symbol may be determined. In addition, it may be configured that a terminal device does not need to receive the data transmitted from the stopping position to the end of the ending symbol, if the terminal device is to perform transmission in a further slot immediately after the ending symbol.

In some embodiments, based on the above determined configuration, the terminal device may obtain the determined configuration so that the data transmitted in the ending symbol is received until the stopping position. That is, the terminal device is not mandated to receive the entire ending symbol 212 of a slot if the UE will perform transmission in a further slot immediately after the ending symbol.

In some other embodiments, in the Tx/Rx switching scenario, from a receiving terminal device perspective, the terminal performs a transmission in a further slot immediately before an initial symbol. For such kind of scenario, a starting position in the initial symbol may be determined. Furthermore, it may be configured that a terminal device does not need to receive the AGC signal transmitted from the beginning of the initial symbol to the starting position, if the terminal device has performed transmission in a further slot immediately before the initial symbol.

In some embodiments, based on the determined configuration as above, the terminal may obtain the determined configuration so that it is started to receive the AGC signal from the starting position in the initial symbol. That is, the terminal device is not mandated to receive the entire initial symbol of a slot if the UE is performing transmission in the previous slot.

In one embodiment, the UE is only expected to receive the last y u s of the initial symbol of a slot. For example, the value of y may be specified. In another example, the value of y may be the time that the UE needed for AGC settling.

FIG. 6 is a schematic diagram shows frequency division multiplexing (FDM) of PSSCH and PSCCH according to some embodiments of the present disclosure.

As shown in FIG. 6, FDMed multiplexing between a PSCCH in a SCORSET 602 and a PSSCH in a PSSCH resource set 604 is provided according to some embodiments of the present disclosure. In addition, AGC on sidelink and Tx/Rx switching are also provided.

The sub-channel 600 comprises a plurality of contiguous resource blocks 202 (RBs) in a same slot 204. The sub-channel 600 may be configured with one or a plurality of SCORESET 602 for the PSCCH per e.g. sub-channel. Alternatively, the one or plurality of SCORESET 602 for the PSCCH may also be configured per resource pool, per bandwidth, per bandwidth part etc. which is not limited herein. Since the principle thereof is the same, the structure will not be repeated herein.

In some embodiments, when one SCORESET 602 is configured or preconfigured, the bandwidth of the SCORESET 602 may be always equal to the resource pool, bandwidth, bandwidth part, or sub-channel. In some other embodiments, when a plurality of SCORESETs 602 are configured (not shown), the initial symbol 206 and duration of each SCORESET 602 are the same, bandwidth of different SCORESET 602 do not overlap with each other.

In some embodiments, one SCORESET 602 is always associated with one PSSCH time-frequency resource set in a slot, and a plurality of SCORESETs may be associated with a single PSSCH time-frequency resource set.

In some embodiments, when only one supportable aggregation level is (pre-)configured in each SCOREST 602, supportable aggregation level for different SCORESET 602 may be different; in case of multiple aggregation levels are supported in each SCORESET 602, the UE may select an aggregation level according to a base station instruction or sidelink channel status.

In some embodiments, the UE transmits PSSCH on the last symbol of the slot.

In order to support Tx/Rx switching, from a receiving UE perspective, in some embodiments, the UE is not mandated to receive the entire ending symbol 606 of a slot if the UE will perform transmission in a further slot immediately after the ending symbol. For similar reason, in some other embodiments, the UE is not mandated to receive the entire initial symbol 608 of a slot if the UE is performing transmission in the previous slot. In one embodiment, the UE is only expected to receive the last y u s of the initial symbol 608 of a slot. For example, the value of y may be specified. In another example, the value of y may be the time that the UE needed for AGC settling.

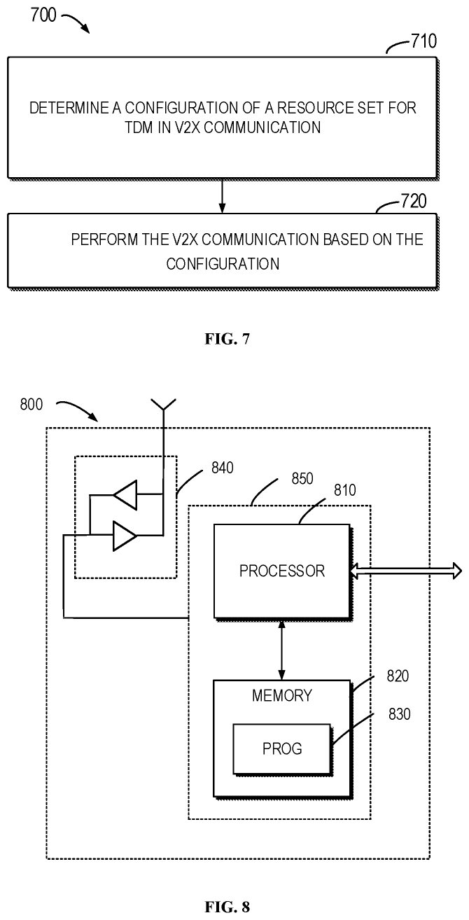

FIG.7 shows a flowchart of a method 700 for sidelink communication according to some embodiments of the present disclosure. The method 700 may be implemented in the terminal device 110 shown in FIG. 1.

As shown in FIG. 7, at block 710, a configuration of a resource set for TDM in V2X communication between a control channel and a data channel is determined. The resource set corresponding to a plurality of symbols in the time domain. The configuration specifying an AGC signal is to be transmitted in an initial symbol of the plurality of symbols. The AGC signal is determined based on control information for the V2X communication with a second terminal device.

At block 720, the V2X communication based on the configuration is determined.

In some embodiments, determining the configuration comprises: configuring, as the AGC signal, a replication of a part of the control information to be transmitted in a symbol after the initial symbol.

In some embodiments, determining the configuration comprises: configuring a part of the control information as the AGC signal, the part being different from the remaining part of the control information to be transmitted in one or more symbols after the initial symbol.

In some embodiments, determining the configuration of the resource set comprises: receiving the configuration from the second terminal device or a network device managing the first and second terminal devices.

In some embodiments, determining the configuration comprises: configuring that data for the V2X communication is to be transmitted in an ending symbol of the plurality of symbols. In some further embodiments, determining the configuration further comprises: determining a stopping position in the ending symbol; and configuring that a terminal device does not need to receive the data from the stopping position to the end of the ending symbol, if the terminal device is to perform transmission in a further slot immediately after the ending symbol.

In some embodiments, determining the configuration comprises: determining a starting position in the initial symbol; and configuring that a terminal device does not need to receive the AGC signal from the beginning of the initial symbol to the starting position, if the terminal device has performed transmission in a further slot immediately before the initial symbol.

In some embodiments, performing the V2X communication comprises: in response to the configuration specifying that the AGC signal is a replication of a part of the control information to be transmitted in a symbol after the initial symbol based on the configuration, transmitting the replication as the AGC signal in the initial symbol from the first terminal device to the second terminal device.

In some embodiments, performing the V2X communication comprises: in response to the configuration specifying that the AGC signal is a part of the control information different from the remaining part of the control information to be transmitted in one or more symbols after the initial symbol, transmitting the part of the control information in the initial symbol from the first terminal device to the second terminal device.

In some embodiments, performing the V2X communication comprises: receiving, at the first terminal device, the AGC signal in the initial symbol from the second terminal device, the AGC signal being a replication of a part of the control information to be transmitted in a symbol after the initial symbol; or receiving, at the first terminal device, the AGC signal in the initial symbol from the second terminal device, the AGC signal being a part of the control information different from the remaining part of the control information to be transmitted in one or more symbols after the initial symbol.

In some embodiments, performing the V2X communication comprises: in response to the configuration specifying that a terminal device does not need to receive data for the V2X communication from a stopping position to the end of an ending symbol of the plurality of symbols, obtaining, from the configuration, the stopping position in the ending symbol; and in response to that the first terminal device is to perform transmission in a further slot immediately after the ending symbol, receiving the data transmitted in the ending symbol until the stopping position.

In some embodiments, performing the V2X communication comprises: in response to the configuration specifying that a terminal device does not need to receive the AGC signal from the beginning of the initial symbol to a starting position, obtaining, from the configuration, the starting position in the initial symbol; and in response to that the first terminal device has performed transmission in a further slot immediately before the initial symbol, starting reception of the AGC signal from the starting position in the initial symbol.

In some embodiments, determining the configuration comprises: configuring that, if a terminal device does not transmit both control information and data associated with the control information on the same symbol, a first transmission power of the control information is to be proportional to a second transmission power of the data.

In some embodiments, performing the V2X communication comprises: in response to that the first terminal device does not transmit both control information and data associated with the control information on the same symbol, transmitting the control information with a first transmission power and the data with a second transmission power, the first transmission power being proportional to the second transmission power.

In some embodiments, determining the configuration comprises: configuring that, if a terminal device transmits both control information and data associated with the control information on the same symbol, a difference between a maximum transmission power and a minimum transmission power of transmission powers on the plurality of the symbols is less than a threshold difference; or a transmission power of a symbol where the control information is transmitted is the same as a transmission power of a symbol where only the data is transmitted.

In some embodiments, performing the V2X communication comprises:

In some embodiments, in response to that the first terminal device transmits both control information and data associated with the control information on the same symbol, transmitting the control information and the data, such that a difference between a maximum transmission power and a minimum transmission power of transmission powers on the plurality of the symbols is less than a threshold difference, or transmitting the control information and the data, such that a transmission power of a symbol where the control information is transmitted is the same as a transmission power of a symbol where only the data is transmitted.

FIG. 8 is a simplified block diagram of a device 800 that is suitable for implementing embodiments of the present disclosure. The device 800 may be considered as a further example implementation of a terminal device 110 as shown in FIG. 1. Accordingly, the device 800 can be implemented at or as at least a part of the terminal device 110.

As shown, the device 800 includes a processor 810, a memory 820 coupled to the processor 810, a suitable transmitter (TX) and receiver (RX) 840 coupled to the processor 810, and a communication interface coupled to the TX/RX 840. The memory 810 stores at least a part of a program 830. The TX/RX 840 is for bidirectional communications. The TX/RX 840 has at least one antenna to facilitate communication, though in practice an Access Node mentioned in this application may have several ones. The communication interface may represent any interface that is necessary for communication with other network elements, such as X2 interface for bidirectional communications between eNBs, S1 interface for communication between a Mobility Management Entity (MME)/Serving Gateway (S-GW) and the eNB, Un interface for communication between the eNB and a relay node (RN), or Uu interface for communication between the eNB and a terminal device.

The program 830 is assumed to include program instructions that, when executed by the associated processor 810, enable the device 800 to operate in accordance with the embodiments of the present disclosure, as discussed herein with reference to FIGS. 2 to 7. The embodiments herein may be implemented by computer software executable by the processor 810 of the device 800, or by hardware, or by a combination of software and hardware. The processor 810 may be configured to implement various embodiments of the present disclosure. Furthermore, a combination of the processor 810 and memory 810 may form processing means 850 adapted to implement various embodiments of the present disclosure.

The memory 810 may be of any type suitable to the local technical network and may be implemented using any suitable data storage technology, such as a non-transitory computer readable storage medium, semiconductor-based memory devices, magnetic memory devices and systems, optical memory devices and systems, fixed memory and removable memory, as non-limiting examples. While only one memory 810 is shown in the device 800, there may be several physically distinct memory modules in the device 800. The processor 810 may be of any type suitable to the local technical network, and may include one or more of general purpose computers, special purpose computers, microprocessors, digital signal processors (DSPs) and processors based on multicore processor architecture, as non-limiting examples. The device 800 may have multiple processors, such as an application specific integrated circuit chip that is slaved in time to a clock which synchronizes the main processor.

Generally, various embodiments of the present disclosure may be implemented in hardware or special purpose circuits, software, logic or any combination thereof. Some aspects may be implemented in hardware, while other aspects may be implemented in firmware or software which may be executed by a controller, microprocessor or other computing device. While various aspects of embodiments of the present disclosure are illustrated and described as block diagrams, flowcharts, or using some other pictorial representation, it will be appreciated that the blocks, apparatus, systems, techniques or methods described herein may be implemented in, as non-limiting examples, hardware, software, firmware, special purpose circuits or logic, general purpose hardware or controller or other computing devices, or some combination thereof.

The present disclosure also provides at least one computer program product tangibly stored on a non-transitory computer readable storage medium. The computer program product includes computer-executable instructions, such as those included in program modules, being executed in a device on a target real or virtual processor, to carry out the process or method as described above with reference to any of FIGS. 2 to 8. Generally, program modules include routines, programs, libraries, objects, classes, components, data structures, or the like that perform particular tasks or implement particular abstract data types. The functionality of the program modules may be combined or split between program modules as desired in various embodiments. Machine-executable instructions for program modules may be executed within a local or distributed device. In a distributed device, program modules may be located in both local and remote storage media.

Program code for carrying out methods of the present disclosure may be written in any combination of one or more programming languages. These program codes may be provided to a processor or controller of a general purpose computer, special purpose computer, or other programmable data processing apparatus, such that the program codes, when executed by the processor or controller, cause the functions/operations specified in the flowcharts and/or block diagrams to be implemented. The program code may execute entirely on a machine, partly on the machine, as a stand-alone software package, partly on the machine and partly on a remote machine or entirely on the remote machine or server.

The above program code may be embodied on a machine readable medium, which may be any tangible medium that may contain, or store a program for use by or in connection with an instruction execution system, apparatus, or device. The machine readable medium may be a machine readable signal medium or a machine readable storage medium. A machine readable medium may include but not limited to an electronic, magnetic, optical, electromagnetic, infrared, or semiconductor system, apparatus, or device, or any suitable combination of the foregoing. More specific examples of the machine readable storage medium would include an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing.

Further, while operations are depicted in a particular order, this should not be understood as requiring that such operations be performed in the particular order shown or in sequential order, or that all illustrated operations be performed, to achieve desirable results. In certain circumstances, multitasking and parallel processing may be advantageous. Likewise, while several specific implementation details are contained in the above discussions, these should not be construed as limitations on the scope of the present disclosure, but rather as descriptions of features that may be specific to particular embodiments. Certain features that are described in the context of separate embodiments may also be implemented in combination in a single embodiment. Conversely, various features that are described in the context of a single embodiment may also be implemented in multiple embodiments separately or in any suitable sub-combination.

Although the present disclosure has been described in language specific to structural features and/or methodological acts, it is to be understood that the present disclosure defined in the appended claims is not necessarily limited to the specific features or acts described above. Rather, the specific features and acts described above are disclosed as example forms of implementing the claims.

1-18. (canceled)

19. A method implemented at a first terminal device, comprising:
determining a configuration of a resource set for Time Division Multiplexing (TDM) in vehicle-to-everything (V2X) communication between a control channel and a data channel, the resource set corresponding to a plurality of symbols in the time domain, the configuration specifying an Automatic Gain Control (AGC) signal is to be transmitted in an initial symbol of the plurality of symbols, the AGC signal being determined based on control information for the V2X communication; and
performing the V2X communication with a second terminal device based on the configuration.

20. The method of claim 19, wherein determining the configuration comprises:
configuring, as the AGC signal, a replication of a part of the control information to be transmitted in a symbol after the initial symbol.

21. The method of claim 19, wherein determining the configuration comprises:
configuring a part of the control information as the AGC signal, the determined part being different from the remaining part of the control information to be transmitted in one or more symbols after the initial symbol.

22. The method of claim 19, wherein determining the configuration of the resource set comprises:
receiving the configuration from the second terminal device or a network device managing the first and second terminal devices.

23. The method of claim 19, wherein determining the configuration comprises:
configuring that data for the V2X communication is to be transmitted in an ending symbol of the plurality of symbols.

24. The method of claim 23, further comprising:
determining a stopping position in the ending symbol; and
configuring that a terminal device does not need to receive the data from the stopping position to the end of the ending symbol, if the terminal device is to perform transmission in a further slot immediately after the ending symbol.

25. The method of claim 19, wherein determining the configuration comprises:
determining a starting position in the initial symbol; and
configuring that a terminal device does not need to receive the AGC signal from the beginning of the initial symbol to the starting position, if the terminal device has performed transmission in a further slot immediately before the initial symbol.

26. The method of claim 19, wherein performing the V2X communication comprises:
in response to the configuration specifying that the AGC signal is a replication of a part of the control information to be transmitted in a symbol after the initial symbol based on the configuration, transmitting the replication as the AGC signal in the initial symbol from the first terminal device to the second terminal device.

27. The method of claim 19, wherein performing the V2X communication comprises:
in response to the configuration specifying that the AGC signal is a part of the control information different from the remaining part of the control information to be transmitted in one or more symbols after the initial symbol, transmitting the part of the control information in the initial symbol from the first terminal device to the second terminal device.

28. The method of claim 19, wherein performing the V2X communication comprises:
receiving, at the first terminal device, the AGC signal in the initial symbol from the second terminal device, the AGC signal being a replication of a part of the control information to be transmitted in a symbol after the initial symbol; or
receiving, at the first terminal device, the AGC signal in the initial symbol from the second terminal device, the AGC signal being a part of the control information different from the remaining part of the control information to be transmitted in one or more symbols after the initial symbol.

29. The method of claim 19, wherein performing the V2X communication comprises:
in response to the configuration specifying that a terminal device does not need to receive data for the V2X communication transmitted from a stopping position to the end of an ending symbol of the plurality of symbols, obtaining, from the configuration, the stopping position in the ending symbol; and
in response to that the first terminal device is to perform transmission in a further slot immediately after the ending symbol, receiving the data transmitted in the ending symbol until the stopping position.

30. The method of claim 19, wherein performing the V2X communication comprises:
in response to the configuration specifying that a terminal device does not need to receive the AGC signal transmitted from the beginning of the initial symbol to a starting position, obtaining, from the configuration, the starting position in the initial symbol; and
in response to that the first terminal device has performed transmission in a further slot immediately before the initial symbol, starting reception of the AGC signal from the starting position in the initial symbol.

31. The method of claim 19, wherein determining the configuration comprises:
configuring that, if a terminal device does not transmit both control information and data associated with the control information on the same symbol, a first transmission power of the control information is to be proportional to a second transmission power of the data.

32. The method of claim 31, wherein performing the V2X communication comprises:
in response to that the first terminal device does not transmit both control information and data associated with the control information on the same symbol, transmitting the control information with a first transmission power and the data with a second transmission power, the first transmission power being proportional to the second transmission power.

33. The method of claim 19, wherein determining the configuration comprises:
configuring that, if a terminal device transmits both control information and data associated with the control information on the same symbol,
a difference between a maximum transmission power and a minimum transmission power of transmission powers on the plurality of the symbols is less than a threshold difference; or
a transmission power of a symbol where the control information is transmitted is the same as a transmission power of a symbol where only the data is transmitted.

34. The method of claim 33, wherein performing the V2X communication comprises:
in response to that the first terminal device transmits both control information and data associated with the control information on the same symbol,
transmitting the control information and the data, such that a difference between a maximum transmission power and a minimum transmission power of transmission powers on the plurality of the symbols is less than a threshold difference, or
transmitting the control information and the data, such that a transmission power of a symbol where the control information is transmitted is the same as a transmission power of a symbol where only the data is transmitted.

35. A terminal device, comprising:
a processor; and
a memory coupled to the processing unit and storing instructions thereon, the instructions, when executed by the processing unit, causing the device to:
determine a configuration of a resource set for Time Division Multiplexing (TDM) in vehicle-to-everything (V2X) communication between a control channel and a data channel, the resource set corresponding to a plurality of symbols in the time domain, the configuration specifying an Automatic Gain Control (AGC) signal is to be transmitted in an initial symbol of the plurality of symbols, the AGC signal being determined based on control information for the V2X communication; and
perform the V2X communication with a second terminal device based on the configuration.

36. The device of claim 35, wherein the instructions, when executed by the processing unit, cause the device to:
configuring, as the AGC signal, a replication of a part of the control information to be transmitted in a symbol after the initial symbol.

37. The device of claim 35, wherein the instructions, when executed by the processing unit, cause the device to:
configuring a part of the control information as the AGC signal, the determined part being different from the remaining part of the control information to be transmitted in one or more symbols after the initial symbol.

38. A computer readable medium having instructions stored thereon, the instructions, when executed on at least one processor, causing the at least one processor to:
determine a configuration of a resource set for Time Division Multiplexing (TDM) in vehicle-to-everything (V2X) communication between a control channel and a data channel, the resource set corresponding to a plurality of symbols in the time domain, the configuration specifying an Automatic Gain Control (AGC) signal is to be transmitted in an initial symbol of the plurality of symbols, the AGC signal being determined based on control information for the V2X communication; and
perform the V2X communication with a second terminal device based on the configuration.
